(19) United States
(12) Patent Application Publication
(10) Pub. No.: US 2024/0079385 A1
(43) Pub. Date: Mar. 7, 2024

(54) MICRO SEMICONDUCTOR CHIP TRANSFERRING STRUCTURE AND DISPLAY DEVICE

(71) Applicant: SAMSUNG ELECTRONICS CO., LTD., Suwon-si (KR)

(72) Inventors: Joonyong PARK, Suwon-si (KR); Dongkyun KIM, Suwon-si (KR); Sanghoon SONG, Suwon-si (KR); Minchul YU, Suwon-si (KR); Kyungwook HWANG, Suwon-si (KR); Junsik HWANG, Suwon-si (KR)

(73) Assignee: SAMSUNG ELECTRONICS CO., LTD., Suwon-si (KR)

(21) Appl. No.: 18/120,166

(22) Filed: Mar. 10, 2023

(30) Foreign Application Priority Data
Sep. 2, 2022 (KR) 10-2022-0111469

(51) Int. Cl. H01L 25/075; H01L 33/38

(52) U.S. Cl. CPC H01L 25/0753; H01L 33/38

(57) ABSTRACT

Provided are a micro semiconductor chip transferring structure and a display device employing a display transferring structure. A transferring structure includes a transfer substrate having a plurality of grooves, and a plurality of micro semiconductor chips transferred to the plurality of grooves, respectively, wherein a minimum space between adjacent two of the plurality of micro semiconductor chips transferred to the plurality of grooves is 100% to 200% inclusive of a width of each of the plurality of micro semiconductor chips.

### CROSS-REFERENCE TO RELATED APPLICATION

This application is based on and claims priority under 35 U. S. C. § 119 to Korean Patent Application No. 10-2022-0111469, filed on Sep. 2, 2022, in the Korean Intellectual Property Office, the disclosure of which is incorporated by reference herein in its entirety.

### BACKGROUND

### 1. Field

The disclosure relates to a micro semiconductor chip transferring structure and a display device.

### 2. Description of the Related Art

Light-emitting diodes (LEDs) use low power and are environment friendly. Accordingly, the industrial demand of LEDs has increased. LEDs are applied to not only lighting devices and liquid crystal display (LCD) backlights but also LED display devices. That is, display devices employing micro-unit LED chips have been developed. To manufacture a micro-LED display device, micro-LEDs are transferred to a substrate. Among methods of transferring micro-LEDs, a pick and place method is frequently used. However, according to this method, as a size of a micro-LED decreases, and a size of a display increases, productivity decreases.

### SUMMARY

Provided are a micro semiconductor chip transferring structure by which transfer efficiency may be improved, and a display device employing a display transferring structure.

Additional aspects will be set forth in the description which follows and, additional aspects will be apparent from the express description, or may be learned by practice of example embodiments of the disclosure.

According to an aspect of the disclosure, a transferring structure includes a transfer substrate having a plurality of grooves, and a plurality of micro semiconductor chips transferred to the plurality of grooves, respectively, each of the plurality of micro semiconductor chips having a width w2, wherein a minimum space between adjacent two of the plurality of micro semiconductor chips transferred to the plurality of grooves is 100% to 200% inclusive of width w2.

A width of each of the plurality of grooves may be greater than 100% and less than 150% of the width of each of the plurality of micro semiconductor chips.

The micro semiconductor chip may have a plurality of electrodes, and positions of the plurality of electrodes may form point symmetry with reference to a central part of the micro semiconductor chip.

Each of the plurality of grooves may have a size such that each of the plurality of micro semiconductor chips is movable therein, and each of the plurality of micro semiconductor chips may be located at a same position inside a respective one of the plurality of grooves.

A depth of each of the plurality of grooves may be less than a thickness of the micro semiconductor chip.

Each of the plurality of grooves may have a size such that each of the plurality of micro semiconductor chips may be accommodated therein.

A bottom surface of each of the plurality of grooves may have a planar shape with a short side and a long side that is perpendicular to the short side, the short side may be greater than the width of the micro semiconductor chip and less than or equal to two times the width of the micro semiconductor chip, and the long side may be greater than two times the width of the micro semiconductor chip.

The long side may be greater than or equal to three times the width of the micro semiconductor chip and less than four times the width of the micro semiconductor chip.

A bottom surface of each of the plurality of grooves may have an L shape.

According to another aspect of the disclosure, a transfer substrate may have a plurality of grooves into which at least one micro semiconductor chip is inserted,

wherein a distance between adjacent two of the plurality of grooves is 80% to 170% inclusive of a width of a bottom surface of the groove.

The distance between adjacent two of the plurality of grooves is 100% to 130% inclusive of the width of the bottom surface of the groove.

According to another aspect of the disclosure, a display device includes a display transferring structure to which a plurality of micro semiconductor chips are transferred, wherein a spacing of the plurality of micro semiconductor chips satisfy Equation 1 below:

$$100 ( \% ) \leq \frac{a}{b} \times 100 ( \% ) \leq 200 ( \% ) \qquad Equation 1$$

where a denotes a minimum space between adjacent two of the plurality of micro semiconductor chips, and b denotes a size of the micro semiconductor chip.

The spacing of the plurality of micro semiconductor chips may satisfy Equation 2 below:

$$120 ( \% ) \leq \frac{a}{b} \times 100 ( \% ) \leq 160 ( \% ) \qquad Equation 2$$

The plurality of micro semiconductor chips may have a diamond pentile pixel arrangement.

### BRIEF DESCRIPTION OF THE DRAWINGS

The above and other aspects, features, and advantages of example embodiments of the disclosure will be more apparent from the following description taken in conjunction with the accompanying drawings, in which:

FIG. 1 is a perspective view of a transferring structure according to an embodiment;

FIG. 2 is a perspective view of a transfer substrate according to an embodiment;

FIG. 3 is a cross-sectional view of a transfer substrate according to an embodiment;

FIG. 4 is a cross-sectional view of a micro semiconductor chip according to an embodiment;

FIG. 5 is a cross-sectional view of a micro semiconductor chip and a portion of a transfer substrate according to an embodiment;

FIG. 6 is a top view illustrating a process of transferring a micro semiconductor chip in an empty groove of a transfer substrate, according to a comparative example;

FIG. 7 is a top view illustrating micro semiconductor chips transferred to a transfer substrate and a non-transferred micro semiconductor chip on a transferring structure, according to an embodiment;

FIG. 8 is a top view illustrating a transferring structure having a plurality of micro semiconductor chips transferred to all grooves of a transfer substrate, according to an embodiment;

FIG. 9 is a top view illustrating micro semiconductor chips transferred to a transfer substrate, of which each groove may accommodate two or more micro semiconductor chips, and a non-transferred micro semiconductor chip on a transferring structure, according to an embodiment;

FIG. 10 is a top view illustrating micro semiconductor chips transferred to a transfer substrate, of which each groove may accommodate two or more micro semiconductor chips, and a non-transferred micro semiconductor chip on a transferring structure, according to an embodiment;

FIG. 11 is a top view illustrating micro semiconductor chips transferred to a transfer substrate, of which each bent groove may accommodate two or more micro semiconductor chips, and a non-transferred micro semiconductor chip on a transferring structure, according to an embodiment;

FIG. 12 is a top view of shapes of various grooves according to an embodiment;

FIG. 13 is a top view of a micro semiconductor chip according to an embodiment;

FIG. 14 is a top view of a micro semiconductor chip according to an embodiment;

FIG. 15 is a flowchart illustrating a micro semiconductor chip wet alignment method according to an embodiment;

FIG. 16 is a perspective view of a micro semiconductor chip wet alignment apparatus according to an embodiment;

FIG. 17 is a perspective view illustrating a sweeping process in a micro semiconductor chip wet alignment method on a transfer substrate, according to a comparative example;

FIG. 18 is a perspective view illustrating a sweeping process in a micro semiconductor chip wet alignment method on a transfer substrate, according to an embodiment;

FIG. 19 is a magnified cross-sectional view of a groove in a process of aligning a micro semiconductor chip by a micro semiconductor chip wet alignment method, according to an embodiment;

FIG. 20 is a flowchart illustrating a method of transferring micro semiconductor chips to grooves;

FIG. 21 is a top view illustrating a state in which micro semiconductor chips are transferred to a transferring structure, according to an embodiment;

FIG. 22 is a top view illustrating a state in which micro semiconductor chips are transferred to a transferring structure, according to an embodiment;

FIG. 23 is a cross-sectional view illustrating a process of transferring a plurality of micro semiconductor chips to a driving substrate, according to an embodiment;

FIG. 24 is a front view illustrating a structure in which a plurality of micro semiconductor chips are transferred to a driving substrate;

FIG. 25 is a top view illustrating a structure in which a plurality of micro semiconductor chips are transferred to a driving substrate;

FIG. 26 is a top view illustrating a structure in which a plurality of micro semiconductor chips are transferred to a driving substrate to make a pattern;

FIG. 27 is a block diagram of an electronic device including a display device, according to an embodiment;

FIG. 28 illustrates an example in which an electronic device is applied to a mobile device, according to an embodiment;

FIG. 29 illustrates an example in which a display device is applied to a vehicle, according to an embodiment;

FIG. 30 illustrates an example in which a display device is applied to augmented reality glasses or virtual reality glasses, according to an embodiment;

FIG. 31 illustrates an example in which a display device is applied to a large-scale signage, according to an embodiment; and

FIG. 32 illustrates an example in which a display device is applied to a wearable display, according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items.

Hereinafter, a micro semiconductor chip transferring structure and a display device according to various embodiments are described in detail with reference to the accompanying drawings. The size or thickness of each element may be exaggerated for clarity and convenience of description. Though terms like ‘first’ and ‘second’ are used to describe various elements, the elements are not limited to these terms. These terms are used only to differentiate an element from another element.

An expression in the singular includes an expression in the plural unless they are clearly different from each other in context. In addition, when a certain part “includes” a certain component, this indicates that the part may further include another component instead of excluding another component unless specifically stated or inferred by context.

The use of the term “said” or a similar antecedent term may correspond to both the singular and the plural.

For steps forming methods, if there is no disclosure requiring a clear order, the steps may be performed in any order deemed proper. The use of all illustrations or illustrative terms (for example, and so forth, etc.) is simply to describe the technical idea, and the scope is not limited due to the illustrations or illustrative terms.

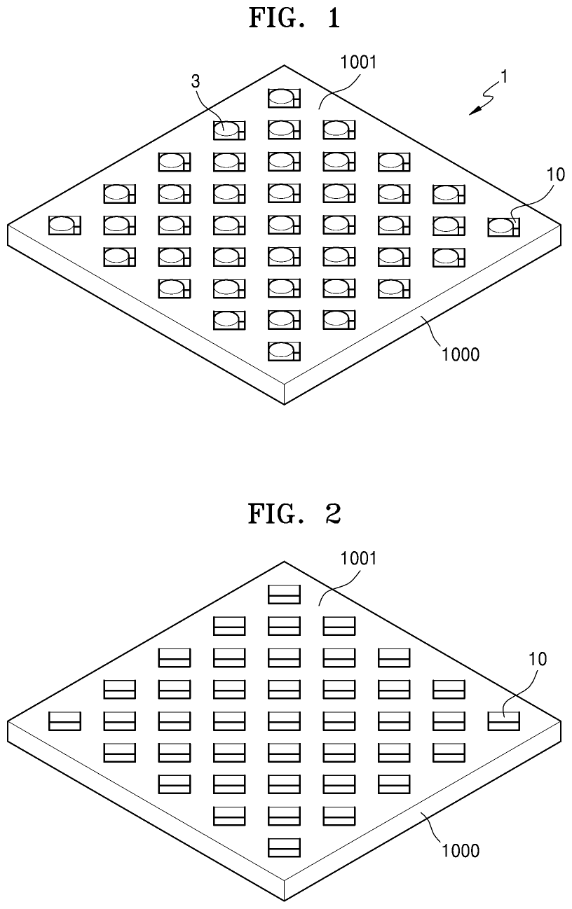

FIG. 1 is a perspective view of a transferring structure 1 according to an embodiment.

Referring to FIG. 1, the transferring structure 1 according to an embodiment may include a transfer substrate 1000 and a plurality of micro semiconductor chips 3 transferred to the transfer substrate 1000.

The transfer substrate 1000 according to an embodiment may include a plurality of grooves 10. The transfer substrate 1000 may be a single body or single mold structured substrate including the plurality of grooves 10. The transfer substrate 1000 may include an upper surface 1001.

The transfer substrate 1000 may include silicon, glass, sapphire, an organic material, such as a polymer, an inorganic material, and/or a metal and be produced by photoresist patterning, etching, molding, or the like but is not limited thereto.

The plurality of grooves 10 may guide transferring of the micro semiconductor chip 3 as the micro semiconductor chip 3 is transferred to the transfer substrate 1000. For example, the plurality of grooves 10 may guide the plurality of micro semiconductor chips 3 to be transferred at certain intervals or positions.

The plurality of grooves 10 may be formed by being depressed by a certain depth from the upper surface 1001. A micro semiconductor chip 3 may be inside each of the plurality of grooves 10. The groove 10 may have a cross-sectional area that is greater than an area of the micro semiconductor chip 3 to accommodate the micro semiconductor chip 3 therein. Each of the plurality of grooves 10 may have such an area that only one micro semiconductor chip 3 is accommodated or that two or more micro semiconductor chips 3 may be accommodated. As shown in FIG. 1, one micro semiconductor chip 3 may be in the groove 10. However, a shape of the groove 10 is not limited thereto, and two or more micro semiconductor chips 3 may be accommodated in the groove 10.

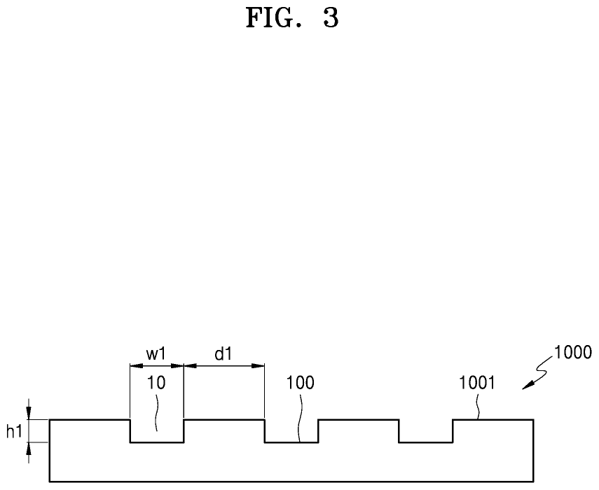

FIG. 2 is a perspective view of the transfer substrate 1000 according to an embodiment. Referring to FIG. 2, the plurality of grooves 10 may be arranged in a diamond pentile pixel structure. Sizes of the plurality of grooves 10 may be identical to each other. The plurality of grooves 10 may have a circular or polygonal cross-section. The plurality of grooves 10 may have a square or rectangular shape. The plurality of grooves 10 may have a different cross-sectional shape from that of the micro semiconductor chip 3. For example, the cross-sectional shape of the groove 10 may be a rectangular shape, while the cross-sectional shape of the micro semiconductor chip 3 is a circular shape. However, the shape of the groove 10 is not limited thereto. For example, the plurality of grooves 10 may have a cross-sectional shape corresponding or similar to that of the micro semiconductor chip 3. For example, the cross-sectional shape of the groove 10 may be a rectangular shape, while the cross-sectional shape of the micro semiconductor chip 3 is a rectangular shape. FIG. 3 is a cross-sectional view of the transfer substrate 1000 according to an embodiment.

Referring to FIG. 3, each of the plurality of grooves 10 may include a bottom surface 100. The bottom surface 100 may have roughness of less than or equal to 50 nm.

Each of the plurality of grooves 10 may have a width w1 of the bottom surface 100. When the plurality of grooves 10 have a rectangular shape, the width w1 of the bottom surface 100 may be a width of a short side. Each of the plurality of grooves 10 may have a depth h1. A distance d1 between adjacent two of the plurality of grooves 10 may be a distance from each groove 10 to an adjacent groove 10.

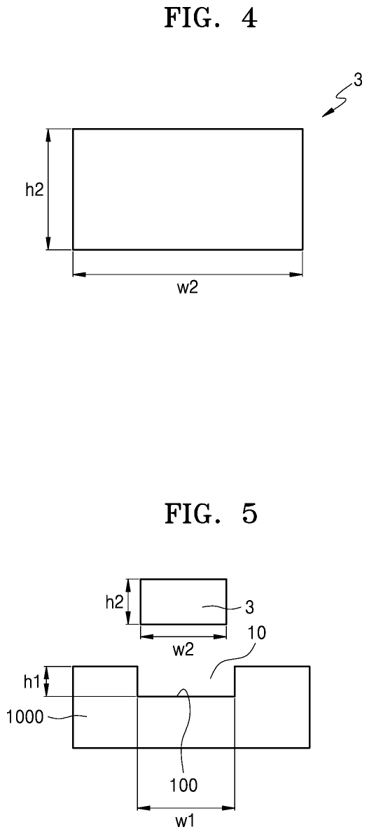

FIG. 4 is a cross-sectional view of the micro semiconductor chip 3 according to an embodiment.

The micro semiconductor chip 3 may include various types of semiconductor chips having a micro size, and the micro size may be less than or equal to 1000 μm or 200 μm. The micro semiconductor chip 3 may include, for example, a light-emitting diode (LED), a complementary metal-oxide semiconductor (CMOS), a CMOS image sensor (CIS), a vertical-cavity surface-emitting laser (VCSEL), a photodiode (PD), a memory device, a two-dimensional (2D) material device, or the like. A 2D material may be graphene, a carbon nanotube (CNT), or the like.

The micro semiconductor chip 3 may include a plurality of electrodes. The micro semiconductor chip 3 may have a certain thickness h2. The micro semiconductor chip 3 may have a certain width w2.

FIG. 5 is a cross-sectional view of the micro semiconductor chip 3 and a portion of the transfer substrate 1000 according to an embodiment.

Referring to FIG. 5, to transfer the micro semiconductor chip 3 to the groove 10, a size of the groove 10 may be greater than a size of the micro semiconductor chip 3. The size of the groove 10 may be greater by about 20% than the size of the micro semiconductor chip 3.

For example, the width w1 of the bottom surface 100 of the groove 10 may be greater than the width w2 of the micro semiconductor chip 3. For example, the width w1 of the bottom surface 100 of the groove 10 may be greater by about 20% than the width w2 of the micro semiconductor chip 3. In this case, a relationship of (w1)*(5/6)=w2 may be established between the width w1 of the bottom surface 100 and the width w2 of the micro semiconductor chip 3.

However, the relationship between the size of the groove 10 and the size of the micro semiconductor chip 3 is not limited to 20% and may be variously changed within a range, including 5%, 10%, 15%, 20%, 25%, 30%, 35%, 40%, 45%, 50%, or the like, which those of ordinary skill in the art could easily change. For example, the width w1 of the bottom surface 100 of the groove 10 may be determined in a range of 105% to 150% of the width w2 of the micro semiconductor chip 3.

The thickness h2 of the micro semiconductor chip 3 may be greater than the depth h1 of the groove 10. Accordingly, a portion of the micro semiconductor chip 3 transferred to the groove 10 may protrude outside the groove 10. For example, when the micro semiconductor chip 3 is transferred to the groove 10 in a state in which an electrode of the micro semiconductor chip 3 faces upward, an upper end part of the electrode may be at a higher position than the upper surface 1001 (see FIG. 3) of the transfer substrate 1000.

In the transferring structure 1 (see FIG. 1) according to an embodiment, a wet scheme may be employed to transfer the plurality of micro semiconductor chips 3 to the plurality of grooves 10, respectively. For example, as a transfer scheme, a fluid self-assembly scheme may be used.

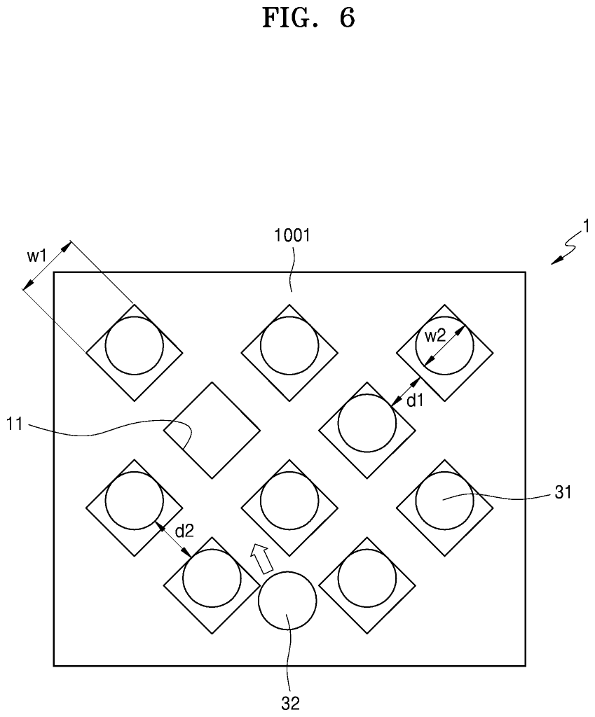

In a transfer process of this wet scheme, the plurality of micro semiconductor chips 3 may be transferred in bulk to the plurality of grooves 10. However, in such a bulk transfer scheme, the micro semiconductor chip 3 may not be transferred to some grooves 10 of the transfer substrate 1000 during a transfer process. In other words, the micro semiconductor chip 3 is transferred to most grooves 10 of the transfer substrate 1000, but the micro semiconductor chip 3 may not be transferred to some grooves 10. In this case, a non-transferred micro semiconductor chip 32 (see FIG. 6) may be moved to be transferred to an empty groove 10.

FIG. 6 is a top view illustrating a process of transferring a micro semiconductor chip 32 in an empty groove 11 of a transfer substrate, according to a comparative example.

Referring to FIG. 6, the non-transferred micro semiconductor chip 32 may be moved to the empty groove 11. The non-transferred micro semiconductor chip 32 may be moved to the empty groove 11 by flow of a fluid used in a wet transfer. The non-transferred micro semiconductor chip 32 may be moved to the empty groove 11 by movement of an absorber 140 (see FIG. 16) used in a wet transfer. The non-transferred micro semiconductor chip 32 may be moved to the empty groove 11 by relative movement of the transferring structure 1. An upper part of a micro semiconductor chip 31 already transferred to the groove 10 may be at a higher position than the upper surface 1001 of the transferring structure 1. The micro semiconductor chip 31 already transferred to the groove 10 may protrude outside the groove 10. The non-transferred micro semiconductor chip 32 may move on the upper surface 1001. It may be difficult for the non-transferred micro semiconductor chip 32 to move over the already transferred micro semiconductor chip 31. The already transferred micro semiconductor chip 31 protruding outside the groove 10 may act as a threshold when the non-transferred micro semiconductor chip 32 moves. While the non-transferred micro semiconductor chip 32 is moving on the transferring structure 1 toward the empty groove 11, the already transferred micro semiconductor chip 31 may interrupt the movement of the non-transferred micro semiconductor chip 32. In particular, if a plurality of already transferred micro semiconductor chips 31 exist on a movement path of the non-transferred micro semiconductor chip 32, the plurality of micro semiconductor chips 31 act as a plurality of thresholds, and thus, the movement of the non-transferred micro semiconductor chip 32 may be difficult.

As described above, because the already transferred micro semiconductor chip 31 acts as a threshold or blockage, it is difficult for the non-transferred micro semiconductor chip 32 to move over the already transferred micro semiconductor chip 31. The non-transferred micro semiconductor chip 32 may move between a plurality of already transferred micro semiconductor chips 31. Mobility of the non-transferred micro semiconductor chip 32 on the transferring structure 1 may depend on an arrangement of the plurality of already transferred micro semiconductor chips 31. When a minimum space width d2 between already transferred micro semiconductor chips 31 is narrow, the movement of the non-transferred micro semiconductor chip 32 may be difficult. When the distance d1 between adjacent two of the plurality of grooves 10 is narrow, movement interruption may also be severe as well. This phenomenon may be worsened when the minimum space width d2 between already transferred micro semiconductor chips 31 is narrow in a device, such as a wearable display, requiring high pixels per inch (PPI). For example, when micro semiconductor chips 3 are transferred to produce the transferring structure 1 of a display requiring 300 or more PPI, this phenomenon may be worse than in lesser density situation.

When a total area of the upper surface 1001 of the transferring structure 1 is proportionally less than a total area of the plurality of grooves 10 of the transferring structure 1, the movement of the non-transferred micro semiconductor chip 32 may be difficult.

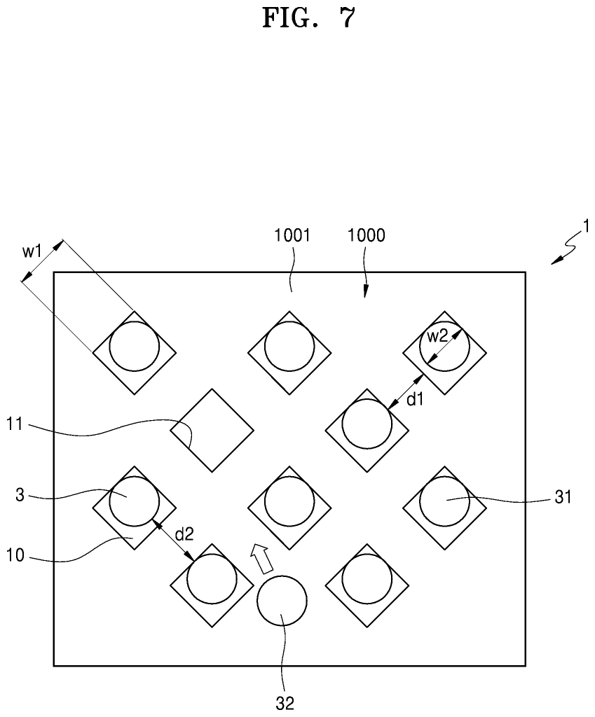

FIG. 7 is a top view illustrating micro semiconductor chips 31 already transferred to a transfer substrate and a non-transferred micro semiconductor chip 32 on the transferring structure 1, according to an embodiment.

Referring to FIG. 7, for the transfer substrate 1000 according to an embodiment, the size of the micro semiconductor chip 3, the minimum space width d2 between micro semiconductor chips 3, or the distance d1 between grooves 10 may be designed for the micro semiconductor chip 3 to easily move to an empty groove 11.

For example, the minimum space width d2 between adjacent two of the plurality of micro semiconductor chips 3 respectively transferred to the plurality of grooves 10 may be greater than or equal to 100% of the width w2 of the micro semiconductor chip 3. For example, the minimum space width d2 between adjacent two of the plurality of micro semiconductor chips 3 respectively transferred to the plurality of grooves 10 may be greater than or equal to 120% of the width w2 of the micro semiconductor chip 3.

However, the minimum space width d2 between micro semiconductor chips 3 may be less than or equal to 200% of the width w2 of the micro semiconductor chip 3 when considering real size limitation of the micro semiconductor chip 3 and the necessity of integration of the plurality of micro semiconductor chips 3.

This may be represented by “movement space ratio” indicating a relationship between the size of the micro semiconductor chip 3 and micro semiconductor chips 31 transferred to the transferring structure 1. The movement space ratio may be defined by Equation 1.

movement space ratio=distance between adjacent two of already transferred micro semiconductor chips 31/size of micro semiconductor chip 3×100(%) [1]

where the size of the micro semiconductor chip 3 may be the width w2 of the micro semiconductor chip 3. A distance between adjacent two of already transferred micro semiconductor chips 31 may be the minimum space width d2 between the already transferred micro semiconductor chips 31. The distance between adjacent two of the already transferred micro semiconductor chips 31 may be a distance between the already transferred micro semiconductor chips 31.

The movement space ratio may be 100% to 200% inclusive.

The movement space ratio may be 120% to 160% inclusive.

The minimum space width d2 between adjacent two of the already transferred micro semiconductor chips 31 may be similar to the distance d1 between adjacent two of the plurality of grooves 10. By considering this feature, a structure for making easy movement of the non-transferred micro semiconductor chip 32 may be defined as the distance d1 between the grooves 10 formed in the transfer substrate 1000. For example, the distance d1 between adjacent two of the plurality of grooves 10 may be greater than or equal to 80% the width w2 of the micro semiconductor chip 3. The distance d1 between adjacent two of the plurality of grooves 10 may be greater than or equal to 100% of the width w2 of the micro semiconductor chip 3.

A structure of the transfer substrate 1000 on which movement of the non-transferred micro semiconductor chip 32 is easy may be represented by the size of the groove 10 and the distance d1 between grooves 10. For example, the distance d1 between grooves 10 may be 80% to 170% inclusive of the width w1 of the bottom surface 100 of the groove 10. For example, the distance d1 between grooves 10 may be 100% to 130% inclusive of the width w1 of the bottom surface 100 of the groove 10.

The minimum space width d2 between adjacent two of the already transferred micro semiconductor chips 31 may be approximately the distance d1 between adjacent two of the plurality of grooves 10. The size of the groove 10 may be approximately the width w1 of the bottom surface 100 of the groove 10.

For example, when considering that the size of the groove 10 may be greater by 20% than the size of the micro semiconductor chip 3, a case where the distance d1 between grooves 10 is greater than or equal to 80% of the width w1 of the bottom surface 100 of the groove 10 may approximately correspond to a case where the movement space ratio is 100%. A case where the distance d1 between grooves 10 is greater than or equal to 100% of the width w1 of the bottom surface 100 of the groove 10 may approximately correspond to a case where the movement space ratio is 120%.

For example, a case where the distance d1 between grooves 10 is less than or equal to 170% of the width w1 of the bottom surface 100 of the groove 10 may approximately correspond to a case where the movement space ratio is 200%. For example, a case where the distance d1 between grooves 10 is less than or equal to 130% of the width w1 of the bottom surface 100 of the groove 10 may approximately correspond to a case where the movement space ratio is 160%.

Referring to FIGS. 6 and 7, movement of the non-transferred micro semiconductor chip 32 when the movement space ratio is 150% may be easier than movement of the non-transferred micro semiconductor chip 32 when the movement space ratio is 90%.

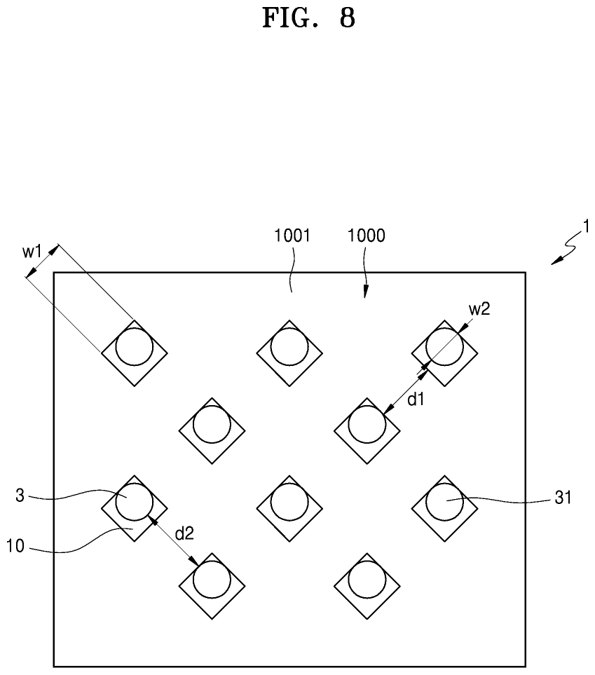

FIG. 8 is a top view illustrating the transferring structure 1 having a plurality of micro semiconductor chips transferred to all grooves of a transfer substrate, according to an embodiment.

Referring to FIG. 8, the micro semiconductor chip 3 is in each of all the grooves 10 of the transferring structure 1. When the movement space ratio (%) is properly adjusted, the micro semiconductor chip 3 may be easily arranged in each of all the grooves 10.

If a process to be described below is employed, irregularity in placement of the plurality of micro semiconductor chips 3 respectively in the plurality of grooves 10 may be reduced so that most micro semiconductor chips 3 are at the same position in respective grooves 10. Although the groove 10 has such a size that the micro semiconductor chip 3 is movable in the groove 10, most micro semiconductor chips 3 may be at the same position in respective grooves 10 by the process to be described below. Each micro semiconductor chip 3 may be aligned in each groove 10 in a particular direction. The particular direction may be any direction only if the particular direction is a planar direction of the transfer substrate 1000. For example, each micro semiconductor chip 3 may be aligned in each groove 10 in an upper left direction of the transfer substrate 1000. Each micro semiconductor chip 3 may be aligned at an upper left end of each groove 10 of the transfer substrate 1000.

Referring back to FIG. 8, one micro semiconductor chip 3 may be transferred to each of the plurality of grooves 10. A width of each of the plurality of grooves 10 may be greater than 100% and less than 150% of the width w2 of the micro semiconductor chip 3. The width w1 of the bottom surface 100 of each of the plurality of grooves 10 may be greater than 100% and less than or equal to 140% of the width w2 of the micro semiconductor chip 3.

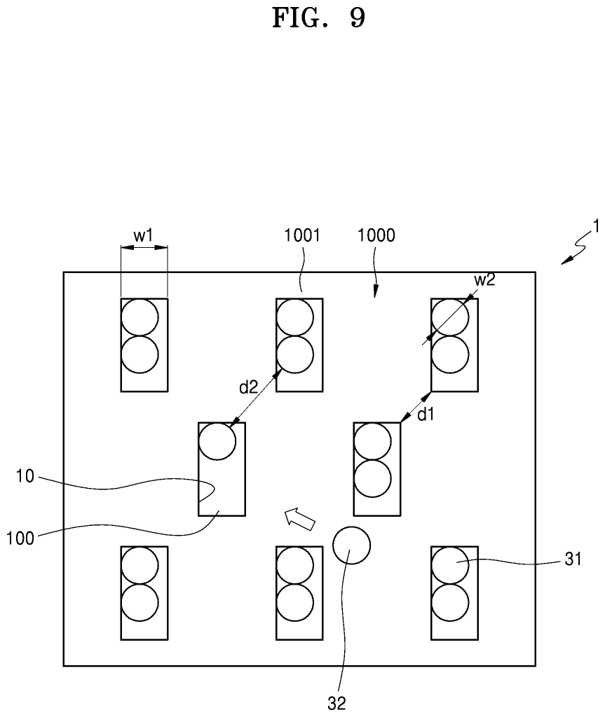

FIG. 9 is a top view illustrating micro semiconductor chips transferred to a transfer substrate, of which each groove may accommodate two or more micro semiconductor chips, and a non-transferred micro semiconductor chip 32 on the transferring structure 1, according to an embodiment.

Referring to FIG. 9, the bottom surface 100 of each of the plurality of grooves 10 may have a rectangular shape. Each bottom surface 100 may have a planar shape with a first width and a second width that is perpendicular to the first width. The first width may be a short side of a rectangle. The second width may be a long side of the rectangle. If the first width differs from the second width, a smaller width may be defined as the width w1 of the bottom surface 100. The first width may be greater than the width w2 of the micro semiconductor chip 3 and less than or equal to two times the width w2 of the micro semiconductor chip 3. The second width may be greater than two times the width w2 of the micro semiconductor chip 3.

Referring to FIG. 9, two or more micro semiconductor chips 3 may be in each groove 10 to form one sub-pixel. Even though one of the two or more micro semiconductor chips 3 in each groove 10 does not operate, if a remaining one micro semiconductor chip 3 operates, the sub-pixel may perform its own function.

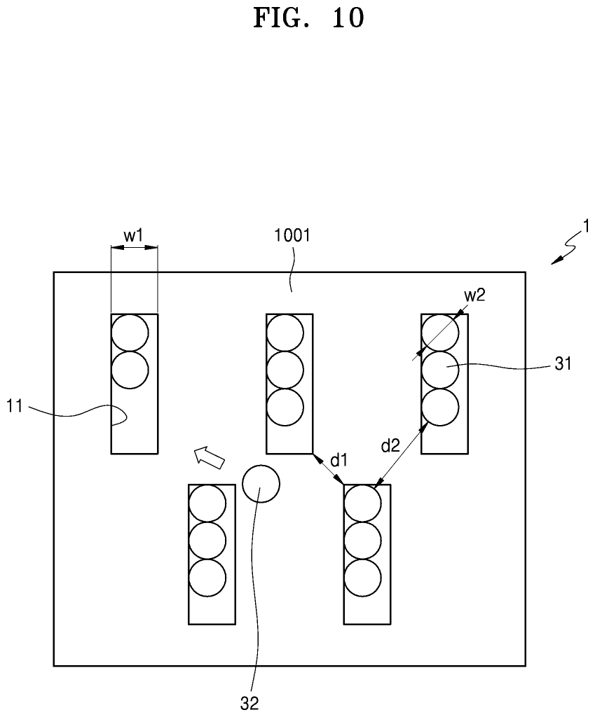

FIG. 10 is a top view illustrating micro semiconductor chips transferred to a transfer substrate, of which each groove may accommodate two or more micro semiconductor chips, and a non-transferred micro semiconductor chip 32 on the transferring structure 1, according to an embodiment.

Referring to FIG. 10, each bottom surface 100 may have a planar shape with a first width and a second width that is perpendicular to the first width. The first width may be a short side of a rectangle. The second width may be a long side of the rectangle. The first width may be greater than the width w2 of the micro semiconductor chip 3 and less than or equal to two times the width w2 of the micro semiconductor chip 3. The second width may be greater than three times the width w2 of the micro semiconductor chip 3. The second width may be less than four times the width w2 of the micro semiconductor chip 3. A case where three micro semiconductor chips 3 are in each groove 10 may have a higher resistance to a defect than a case where two micro semiconductor chips 3 are in each groove 10.

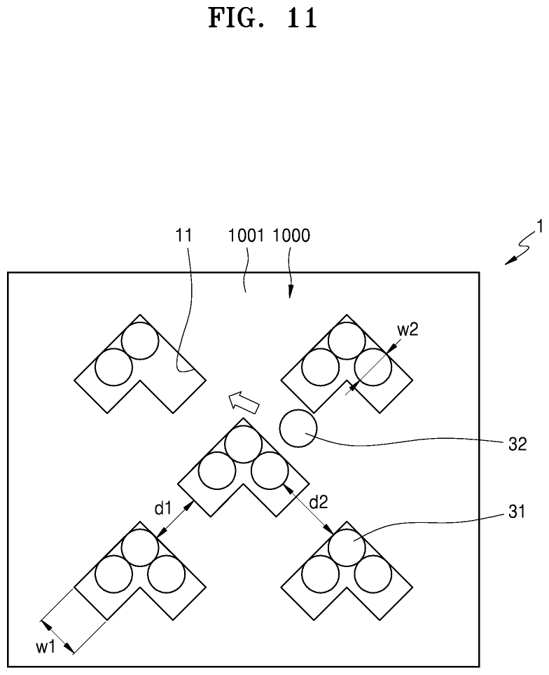

FIG. 11 is a top view illustrating micro semiconductor chips transferred to a transfer substrate, of which each bent groove may accommodate two or more micro semiconductor chips, and a non-transferred micro semiconductor chip 32 on the transferring structure 1, according to an embodiment.

Referring to FIG. 11, the bottom surface 100 of each of the plurality of grooves 10 may have a bent shape. For example, the bottom surface 100 of each of the plurality of grooves 10 may have an L shape. For example, the bottom surface 100 of the groove 10 may have a shape in which a bent portion faces upward. When the bottom surface 100 of the groove 10 has a shape in which a bent portion faces upward, it may be easy to align micro semiconductor chips 3 by sweeping upward.

Cross-sections of each of the plurality of grooves 10 parallel to the transfer substrate 1000 may be constant from the upper surface 1001 to the bottom surface 100. However, the cross-sections of each of the plurality of grooves 10 are not limited thereto and may be various. For example, the cross-sections of each of the plurality of grooves 10 parallel to the transfer substrate 1000 may have a shape of being gradually narrowed from the upper surface 1001 to the bottom surface 100.

FIG. 12 is a top view of shapes of various grooves according to an embodiment.

Referring to FIG. 12, a shape of the bottom surface 100 of each of the plurality of grooves 10 may be a rounded rectangular shape 100a or a rounded bent shape 100b. The shape of the bottom surface 100 of each of the plurality of grooves 10 may be a shape, such as a circular shape 100c, a cross shape 100d, an overlapped quadrangular shape 100e, or an overlapped circular shape 100f, which those of ordinary skill in the art could easily change in the design.

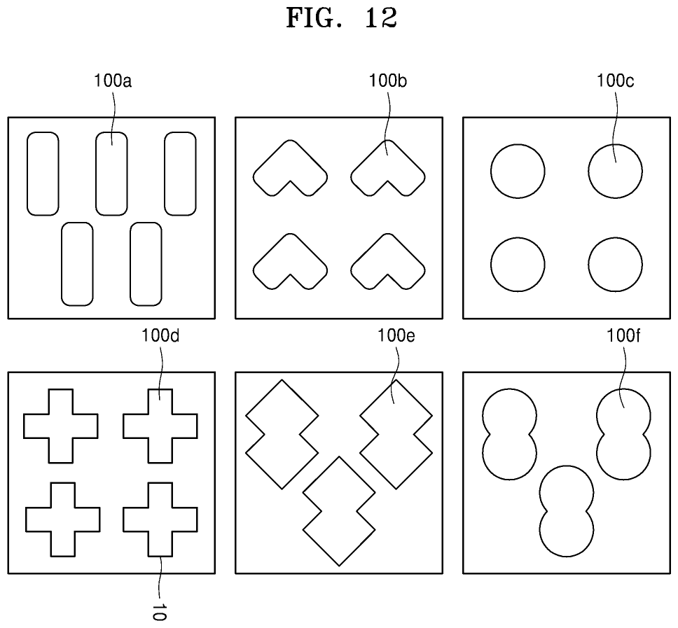

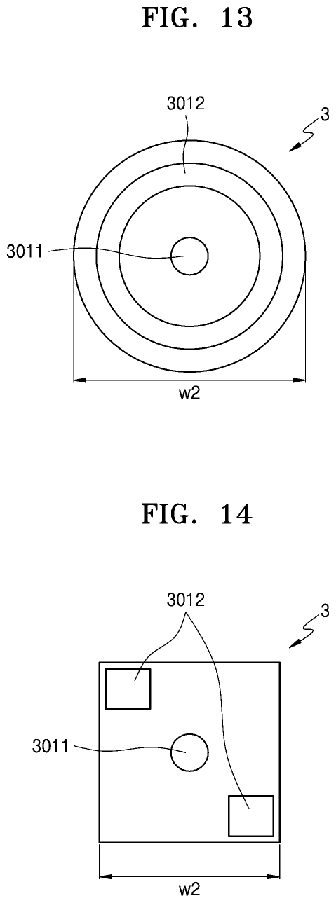

FIG. 13 is a top view of the micro semiconductor chip 3 according to an embodiment.

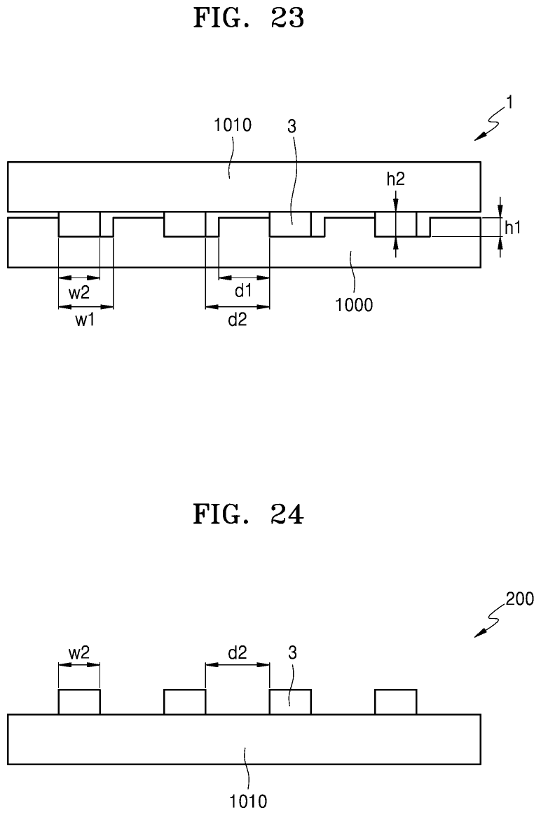

Referring to FIG. 13, the micro semiconductor chip 3 may include a first device electrode 3011 and a second device electrode 3012. The first device electrode 3011 and the second device electrode 3012 may have a symmetrical shape to be easily bonded to corresponding electrodes on a driving substrate 1010 (see FIG. 23). The first device electrode 3011 and the second device electrode 3012 may have a point symmetric shape. The first device electrode 3011 may be at a central part of the micro semiconductor chip 3. The first device electrode 3011 may have a circular shape. However, the first device electrode 3011 is not necessarily limited thereto and may have a quadrangular shape or another polygonal shape. The second device electrode 3012 may be at an edge of the micro semiconductor chip 3. The second device electrode 3012 may have a symmetrical shape with the first device electrode 3011 at the center thereof. For example, the second device electrode 3012 may be respectively at two vertex regions facing each other in a diagonal direction.

By symmetrically arranging the first device electrode 3011 and the second device electrode 3012, the first device electrode 3011 and the second device electrode 3012 may be easily bonded to the corresponding electrodes on the driving substrate 1010 (see FIG. 23). For example, in a process of transferring the micro semiconductor chip 3 to the transfer substrate 1000 in a wet manner, the micro semiconductor chip 3 may rotate. Because the first device electrode 3011 and the second device electrode 3012 are symmetrically arranged, even though the micro semiconductor chip 3 rotates in a process of transferring the micro semiconductor chip 3 to the transfer substrate 1000 in a wet manner, the first device electrode 3011 and the second device electrode 3012 may be easily bonded to the corresponding electrodes on the driving substrate 1010 (see FIG. 23) after the micro semiconductor chip 3 is transferred to the transfer substrate 1000.

FIG. 14 is a top view of the micro semiconductor chip 3 according to an embodiment.

Referring to FIG. 14, the micro semiconductor chip 3 may have a quadrangular shape. The first device electrode 3011 may have a circular shape. The first device electrode 3011 may be at the center of the micro semiconductor chip 3. The second device electrode 3012 may have a quadrangular shape. A plurality of second device electrodes 3012 may be provided. If the number of second device electrodes 3012 is 2, the second device electrodes 3012 may be near both vertices of the micro semiconductor chip 3 in a diagonal direction. The second device electrodes 3012 may be symmetrical to each other with the first device electrode 3011 at the center thereof.

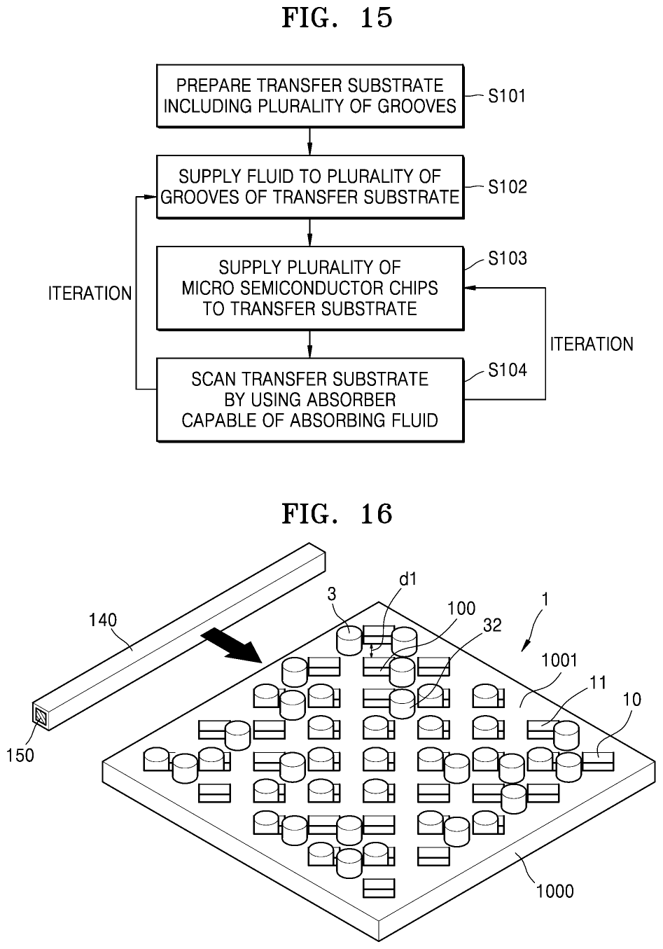

FIG. 15 is a flowchart illustrating a micro semiconductor chip wet alignment method according to an embodiment. FIG. 16 is a perspective view of a micro semiconductor chip wet alignment apparatus according to an embodiment.

The micro semiconductor chip wet alignment method according to an embodiment is described with reference to FIGS. 15 and 16.

In operation S101, the transfer substrate 1000 including the plurality of grooves 10 is prepared. The transfer substrate 1000 may include a single layer or a plurality of layers. The transfer substrate 1000 may be the transfer substrate 1000 according to the embodiments described above. For example, the transfer substrate 1000 may sufficiently ensure the movement space ratio. For example, the movement space ratio (%) of the transfer substrate 1000 may be greater than or equal to 100%. For example, the movement space ratio (%) of the transfer substrate 1000 may be greater than or equal to 120%. For example, the movement space ratio (%) of the transfer substrate 1000 may be less than or equal to 200%. For example, the movement space ratio (%) of the transfer substrate 1000 may be less than or equal to 160%. For example, a distance between adjacent two of the plurality of grooves 10 may be greater than or equal to 80% of a width of the bottom surface 100 of the groove 10. For example, the distance d1 between adjacent two of the plurality of grooves 10 may be greater than or equal to 100% of the width of the bottom surface 100 of the groove 10. For example, the distance d1 between adjacent two of the plurality of grooves 10 may be less than or equal to 170% of the width of the bottom surface 100 of the groove 10. For example, the distance d1 between adjacent two of the plurality of grooves 10 may be less than or equal to 130% of the width of the bottom surface 100 of the groove 10.

The micro semiconductor chip 3 may include various types of semiconductor chips having a micro size, and the micro size may be less than or equal to 1000 μm or 200 μm. The micro semiconductor chip 3 may include, for example, an LED, a CMOS, a CIS, a VCSEL, a PD, a memory device, a 2D material device, or the like. A 2D material may be graphene, a CNT, or the like.

In operation S102, a fluid is supplied to the plurality of grooves 10. As the fluid, any type of fluid may be used unless the fluid corrodes or damages the micro semiconductor chip 3. The fluid may include one a combination of, for example, water, ethanol, alcohol, polyol, ketone, halocarbon, acetone, flux, and an organic solvent. The organic solvent may include, for example, isopropyl alcohol (IPA). A usable fluid is not limited thereto, and various changes are possible.

As a method of supplying the fluid to the plurality of grooves 10, for example, various methods, such as a spray method, a dispensing method, an inkjet dot method, and a method of making the fluid flow through the transfer substrate 1000, may be used. This method is described below. A supply amount of the fluid may be variously adjusted such that the fluid fills the groove 10 or overflows the groove 10.

In operation S103, a plurality of micro semiconductor chips 3 are supplied to the transfer substrate 1000. The plurality of micro semiconductor chips 3 may be directly scattered on the transfer substrate 1000 without another fluid or supplied in a state of being contained in suspension. As a method of supplying micro semiconductor chips 3 contained in the suspension, various methods, such as a spray method, a dispensing method of dripping a fluid drop by drop, an inkjet dot method of ejecting a fluid like printing, and a method of making the suspension flow through the transfer substrate 1000, may be used.

In operation S104, the transfer substrate 1000 is scanned using the absorber 140 capable of absorbing the fluid. The scanning may be sweeping. The absorber 140 just includes a material capable of absorbing the fluid, and a shape or structure of the absorber 140 is not limited. The absorber 140 may include, for example, textile, tissue, polyester fiber, paper, or wiper. The absorber 140 may be used alone without other aids but is not limited thereto, and the absorber 140 may be coupled to a support 150 to easily sweep the transfer substrate 1000. The support 150 may have various shapes and structures suitable for sweeping the transfer substrate 1000. The support 150 may have a shape of, for example, a rod, a blade, a plate, or a wiper. The absorber 140 may be provided to any one surface of the support 150 or surround the periphery of the support 150.

The absorber 140 may sweep the transfer substrate 1000 while pressing the transfer substrate 1000 with proper pressure. The sweeping may include absorbing the fluid while coming in contact with the transfer substrate 1000 and passing through the plurality of grooves 10. The sweeping may be performed by various schemes of, for example, sliding, rotating, translating, reciprocating, rolling, spinning, and/or rubbing of the absorber 140, and include both a regular scheme and an irregular scheme. The sweeping may be performed by moving the transfer substrate 1000 instead of moving the absorber 140, and the sweeping of the transfer substrate 1000 may also be performed by a scheme of sliding, rotating, translating, reciprocating, rolling, spinning, rubbing, and/or the like. Of course, the sweeping may also be performed by cooperation of the absorber 140 and the transfer substrate 1000.

The absorber 140 may perform the sweeping while coming in contact with the surface of the transfer substrate 1000 in a state of being provided to the surface of the support 150. The absorber 140 may move in an arrow direction. The absorber 140 may vibrate in a direction that is perpendicular to a moving direction while moving in the arrow direction. The absorber 140 may move in a zigzag direction. While performing the sweeping, micro semiconductor chips 3 may move by being adsorbed or attached to the surface of the absorber 140. While performing the sweeping, non-transferred micro semiconductor chips 32 are between the absorber 140 and the transfer substrate 1000, and during a process in which the absorber 140 absorbs a fluid L in the plurality of grooves 10, the non-transferred micro semiconductor chips 32 may enter empty grooves 11.

Operation S102 of supplying the fluid to the plurality of grooves 10 of the transfer substrate 1000 and operation S103 of supplying the plurality of micro semiconductor chips 3 to the transfer substrate 1000 may be performed in an opposite order to the order described with reference to FIG. 15. Alternatively, operation S102 of supplying the fluid to the plurality of grooves 10 of the transfer substrate 1000 and operation S103 of supplying the plurality of micro semiconductor chips 3 to the transfer substrate 1000 may be performed at the same time as one operation. For example, the fluid and micro semiconductor chips 3 may be simultaneously supplied to the transfer substrate 1000 by supplying suspension containing the micro semiconductor chips 3 to the transfer substrate 1000. The absorber 140 may push the non-transferred micro semiconductor chips 32 on the transferring structure 1 to the empty grooves 11.

Operations S102 to S104 may be iterated, micro semiconductor chips 3 may be quickly transferred to the transfer substrate 1000 through these operations.

Next, a process of transferring micro semiconductor chips 3 is described in more detail.

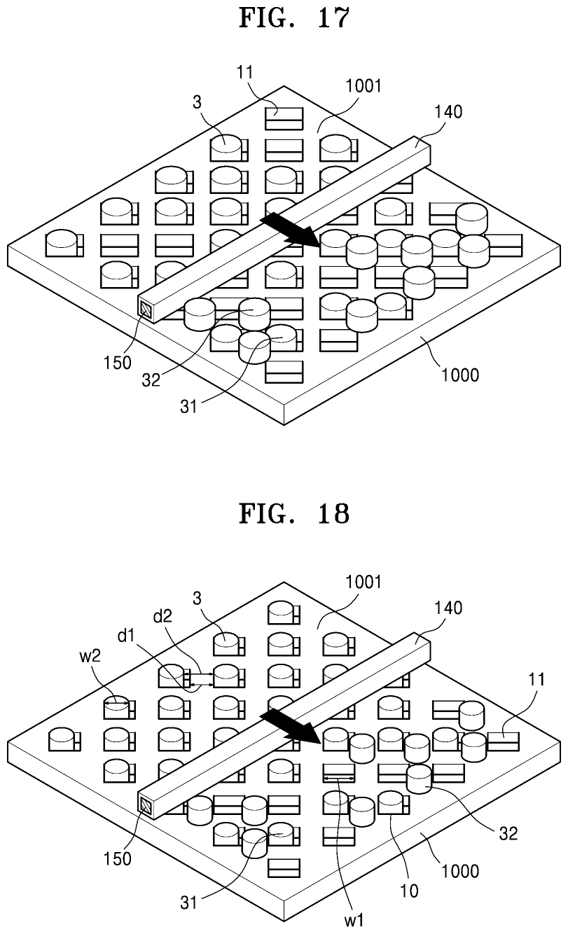

FIG. 17 is a perspective view illustrating a sweeping process in a micro semiconductor chip wet alignment method on the transfer substrate 1000, according to a comparative example.

Referring to FIG. 17, the absorber 140 may perform sweeping while pressing the surface of the transfer substrate 1000. In a structure in which a space for movement of a non-transferred micro semiconductor chip 32 is not sufficiently ensured, when the non-transferred micro semiconductor chip 32 moves along the absorber 140, an already transferred micro semiconductor chip 31 may interrupt the movement of the non-transferred micro semiconductor chip 32. When the non-transferred micro semiconductor chip 32 moves along the absorber 140, the non-transferred micro semiconductor chip 32 may move on the upper surface 1001 of the transferring structure 1. When the non-transferred micro semiconductor chip 32 moves along the absorber 140, the already transferred micro semiconductor chip 31 may act as a threshold. When the already transferred micro semiconductor chip 31 acts as a threshold, the non-transferred micro semiconductor chip 32 may not follow movement of the absorber 140. If a plurality of already transferred micro semiconductor chips 31 exist within an adjacent distance from the non-transferred micro semiconductor chip 32, the plurality of already transferred micro semiconductor chips 31 may act as a plurality of thresholds, and thus, it may be further difficult for the non-transferred micro semiconductor chip 32 to follow the movement of the absorber 140.

Referring to FIG. 17, an empty groove 11 to which a micro semiconductor chip 3 is not transferred may be behind a moving direction of the absorber 140. If the movement space ratio is not sufficient, a micro semiconductor chip 3 may not be well transferred to the empty groove 11.

FIG. 18 is a perspective view illustrating a sweeping process in a micro semiconductor chip wet alignment method on the transfer substrate 1000, according to an embodiment.

The transfer substrate 1000 according to an embodiment may have a structure in which a space for movement of a non-transferred micro semiconductor chip 32 is sufficiently ensured, so that the non-transferred micro semiconductor chip 3 easily enters an empty groove 11. For example, the minimum space width d2 between adjacent two of the plurality of micro semiconductor chips 3 respectively transferred to the plurality of grooves 10 may be 100% to 200% inclusive of the width w2 of each of the plurality of micro semiconductor chips 3. For example, the minimum space width d2 between adjacent two of the plurality of micro semiconductor chips 3 respectively transferred to the plurality of grooves 10 may be 120% to 160% inclusive of the width w2 of each of the plurality of micro semiconductor chips 3. For example, the distance d1 between adjacent two of the plurality of grooves 10 may be 80% to 170% inclusive of the width w1 of the bottom surface 100 of the groove 10. For example, the distance d1 between adjacent two of the plurality of grooves 10 may be 100% to 130% inclusive of the width w1 of the bottom surface 100 of the groove 10.

In the transferring structure 1 according to an embodiment, because a space for movement of a non-transferred micro semiconductor chip 32 is sufficiently ensured, the non-transferred micro semiconductor chip 32 may move without coming in contact with an already transferred micro semiconductor chip 31. For example, when a non-transferred micro semiconductor chip 32 is moved by the absorber 140, the non-transferred micro semiconductor chip 32 may move between already transferred micro semiconductor chips 31 acting as thresholds. Accordingly, the non-transferred micro semiconductor chip 32 may easily move on the transferring structure 1 along the absorber 140. The non-transferred micro semiconductor chip 32 moving along the absorber 140 may easily enter an empty groove 11.

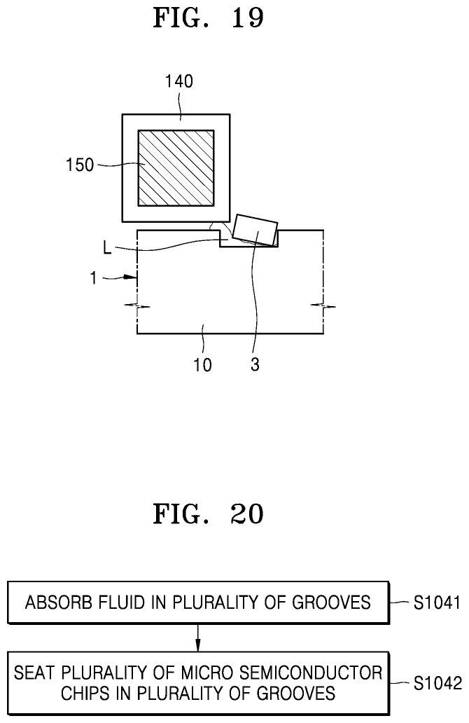

FIG. 19 is a magnified cross-sectional view of a groove 10 in a process of aligning a micro semiconductor chip 3 by a micro semiconductor chip wet alignment method, according to an embodiment.

Referring to FIGS. 18 and 19, while performing sweeping, the micro semiconductor chip 3 is between the absorber 140 and the transfer substrate 1000, and during a process in which the absorber 140 absorbs the fluid L in the grooves 10, the micro semiconductor chip 3, which is not transferred, may enter the groove 10.

FIG. 20 is a flowchart illustrating a method of transferring micro semiconductor chips 3 to grooves 10. Referring to FIGS. 18 to 20, an operation in which the absorber 140 sweeps the transfer substrate 1000 may include operation S1041 of absorbing the fluid L in the plurality of grooves 10 and operation S1042 of seating the plurality of micro semiconductor chips 3 in the plurality of grooves 10. In a process of absorbing the fluid L by the absorber 140, at least a portion of the fluid L in the plurality of grooves 10 may be exchanged with the plurality of micro semiconductor chips 3.

Referring back to FIG. 15, until the plurality of micro semiconductor chips 3 are fully transferred to the plurality of grooves 10 of the transfer substrate 1000, operation S102, operation S103, and/or operation S104 may be iterated according to circumstances. For example, after sweeping the transfer substrate 1000 by the absorber 140, if the fluid disappears or is not sufficient in the plurality of grooves 10, operation S102 of supplying the fluid to the plurality of grooves 10 may be further performed. If micro semiconductor chips 3 on the transfer substrate 1000 are not insufficient, operation S104 may be performed after operation S102 without performing operation S103. If the fluid is too much supplied to the transfer substrate 1000, a blade may be used to remove a portion of the fluid according to circumstances. After sweeping the transfer substrate 1000 by the absorber 140, if micro semiconductor chips 3 on the transfer substrate 1000 are insufficient, operation S103 of supplying micro semiconductor chips 3 to the transfer substrate 1000 may be further performed.

Through the processes described above, the plurality of micro semiconductor chips 3 may be aligned on the transfer substrate 1000. Operation S102, operation S103, and/or operation S104 may be iterated until the plurality of micro semiconductor chips 3 are clearly aligned in the plurality of grooves 10 in sufficient number.

If the movement space ratio (%) is sufficiently ensured, the number of iterations of operation S104 may be reduced. For example, if the movement space ratio (%) is greater than or equal to 100%, the number of iterations of operation S104 may be less than or equal to 5. For example, if the minimum space width d2 between adjacent two of the plurality of micro semiconductor chips 3 respectively transferred to the plurality of grooves 10 is greater than or equal to 100% of the width w2 of each of the plurality of micro semiconductor chips 3, the number of iterations of operation S104 may be less than or equal to 5. For example, if the movement space ratio (%) is greater than or equal to 120%, the number of iterations of operation S104 may be less than or equal to 4. For example, if the minimum space width d2 between adjacent two of the plurality of micro semiconductor chips 3 respectively transferred to the plurality of grooves 10 is greater than or equal to 120% of the width w2 of each of the plurality of micro semiconductor chips 3, the number of iterations of operation S104 may be less than or equal to 4. For example, if the distance d1 between adjacent two of the plurality of grooves 10 is greater than or equal to 80% of the width w1 of the bottom surface 100 of the groove 10, the number of iterations of operation S104 may be less than or equal to 5. For example, if the distance d1 between adjacent two of the plurality of grooves 10 is greater than or equal to 100% of the width w1 of the bottom surface 100 of the groove 10, the number of iterations of operation S104 may be less than or equal to 4.

Although the example described above illustrates an operation of sequentially supplying the fluid and micro semiconductor chips 3 as a method of supplying the fluid and micro semiconductor chips 3 to the transfer substrate 1000, the method of supplying the fluid and micro semiconductor chips 3 is not limited thereto and may be varied. For example, the fluid and micro semiconductor chips 3 may be simultaneously supplied.

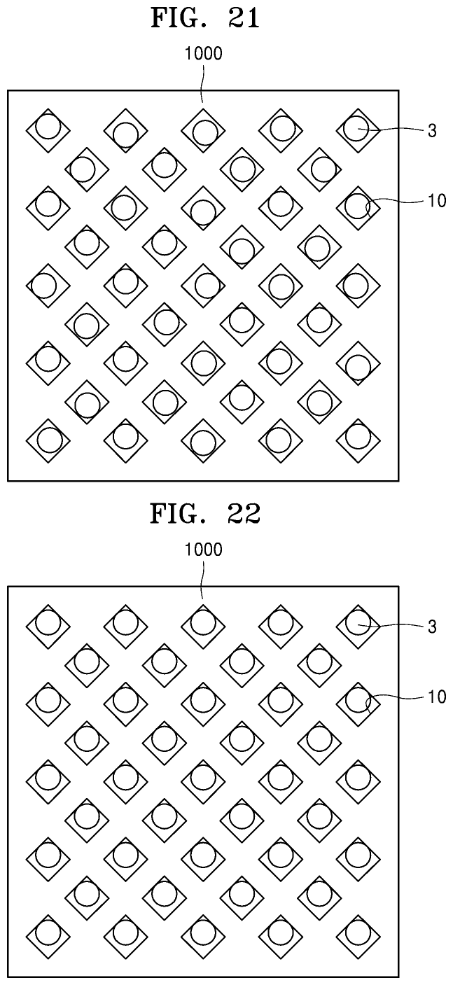

FIGS. 21 and 22 are top views illustrating states in which micro semiconductor chips 3 are transferred to the transferring structure 1000, according to an embodiment.

The micro semiconductor chips 3 transferred according to the wet alignment method described above may be irregularly and randomly positioned within respective grooves 10 of the transfer substrate 1000 as shown in FIG. 21. Unlike micro semiconductor chips 3, aligned according to an existing stamping scheme, of which positions arranged in respective grooves 10 of the transfer substrate 1000 are regular, the micro semiconductor chips 3 aligned according to embodiments of the disclosure may have irregular positions in the respective grooves 10 of the transfer substrate 1000. However, after completely transferring the micro semiconductor chips 3, the irregularity of the irregularly arranged micro semiconductor chips 3 may be reduced by using a clean absorber 140 (see FIG. 16) to sweep the transferring structure 1 one or more times. For example, the clean absorber 140 (see FIG. 16) may be used to sweep the transferring structure 1 several times in a horizontal direction over the transfer substrate 1000. If the irregularity of the micro semiconductor chips 3 is reduced, as shown in FIG. 22, most micro semiconductor chips 3 may be at the same positions in respective grooves 10. The plurality of micro semiconductor chips 3 may be aligned in the plurality of grooves 10 in a proximity direction to one horizontal direction, respectively. Accordingly, the plurality of micro semiconductor chips 3 may be at the same positions in the plurality of grooves 10, respectively.

An operation of transferring micro semiconductor chips 3, according to an embodiment, may include transferring, to the driving substrate 1010 (see FIG. 23), the plurality of micro semiconductor chips 3 transferred to the transfer substrate 1000.

FIG. 23 is a cross-sectional view illustrating a process of transferring the plurality of micro semiconductor chips 3 to the driving substrate 1010, according to an embodiment.

Referring to FIG. 23, the transferring structure 1 may be used to transfer the plurality of micro semiconductor chips 3 to the driving substrate 1010. For example, after arranging the transfer substrate 1000 so that the plurality of micro semiconductor chips 3 face the driving substrate 1010, the plurality of micro semiconductor chips 3 may be transferred to the driving substrate 1010. The driving substrate 1010 may include a plurality of transistors electrically connected to the plurality of micro semiconductor chips 3, respectively. Each of the plurality of micro semiconductor chips 3 may be bonded to the driving substrate 1010. The plurality of micro semiconductor chips 3 may be electrically connected to the driving substrate 1010. The transfer substrate 1000 may be removed after all of the plurality of micro semiconductor chips 3 are transferred to the driving substrate 1010. The transfer substrate 1000 may be removed after the plurality of micro semiconductor chips 3 are bonded to the driving substrate 1010. The transfer substrate 1000 may be removed after the plurality of micro semiconductor chips 3 are electrically connected to the driving substrate 1010. One or more of a process of transferring the plurality of micro semiconductor chips 3 to the driving substrate 1010, a process of bonding the plurality of micro semiconductor chips 3 to the driving substrate 1010, and a process of electrically connecting the plurality of micro semiconductor chips 3 to the driving substrate 1010 may be performed at the same time.

FIG. 24 is a front view illustrating a structure in which the plurality of micro semiconductor chips 3 are transferred to the driving substrate 1010.

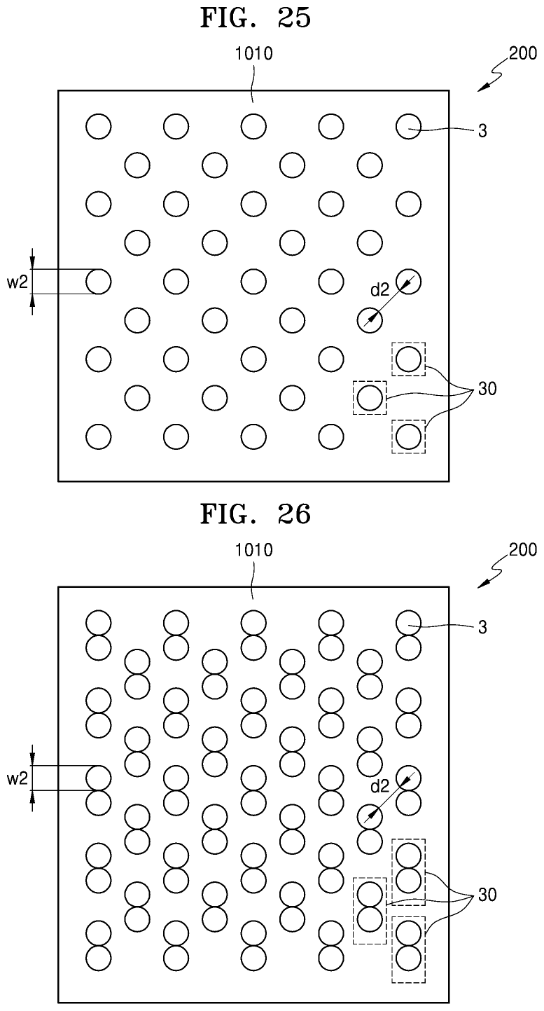

FIG. 25 is a top view illustrating a structure in which the plurality of micro semiconductor chips 3 are transferred to the driving substrate 1010. FIG. 26 is a top view illustrating a structure in which the plurality of micro semiconductor chips 3 are transferred to the driving substrate 1010 to make unit patterns.

Referring to FIGS. 24 and 25, the plurality of micro semiconductor chips 3 transferred to the driving substrate 1010 may be arranged at certain intervals. The minimum space width d2 between adjacent two of the plurality of micro semiconductor chips 3 may be the same as the minimum space width d2 between adjacent two of the micro semiconductor chips 3 in the transferring structure 1 described above. For example, the plurality of micro semiconductor chips 3 may satisfy Equation 2 below.

$$100 ( \% ) \leq \frac{a}{b} \times 100 ( \% ) \leq 200 ( \% ) \qquad Equation 2$$

where a denotes the minimum space width d2 between adjacent two of a plurality of micro semiconductor chips, and b denotes the width w2 of a micro semiconductor chip.

The minimum space width d2 between adjacent two of the plurality of micro semiconductor chips 3 may be 100% to 200% inclusive of the width w2 of the micro semiconductor chip 3.

The plurality of micro semiconductor chips 3 may satisfy Equation 3 below.

$$120 ( \% ) \leq \frac{a}{b} \times 100 ( \% ) \leq 160 ( \% ) \qquad Equation 3$$

where a denotes the minimum space width d2 between adjacent two of a plurality of micro semiconductor chips, and b denotes the width w2 of a micro semiconductor chip.

The minimum space width d2 between adjacent two of the plurality of micro semiconductor chips 3 may be 120% to 160% inclusive of the width w2 of the micro semiconductor chip 3.

A structure in which the plurality of micro semiconductor chips 3 are transferred to the driving substrate 1010 may be a display transferring structure 200. If the plurality of micro semiconductor chips 3 are bonded and electrically connected to the driving substrate 1010, this may be the display transferring structure 200. The display transferring structure 200 may be applied to a display device.

Alternatively, the plurality of micro semiconductor chips 3 may have certain unit patterns 30. According to the unit patterns 30, the plurality of micro semiconductor chips 3 may be arranged in a diamond shape. For example, the plurality of micro semiconductor chips may have a diamond pentile pixel arrangement. According to the unit patterns 30, the plurality of micro semiconductor chips 3 may be separately arranged in a unit of one micro semiconductor chip 3. However, the arrangement of the unit patterns 30 is not limited thereto, and the unit patterns 30 may be separately arranged in a unit of two or more micro semiconductor chips 3. For example, as shown in FIG. 26, the unit patterns 30 may be separately arranged in a unit of two micro semiconductor chips 3.

Referring to FIGS. 22 to 26, the arrangement of the plurality of micro semiconductor chips 3 transferred to the driving substrate 1010 in the display transferring structure 200 may be the same as the arrangement of the plurality of micro semiconductor chips-3 in the transferring structure 1. The arrangement of the plurality of micro semiconductor chips 3 transferred to the driving substrate 1010 in the display transferring structure 200 may be the same as the arrangements of the plurality of micro semiconductor chips 3 in the transferring structure 1 of FIGS. 8 to 11. Each unit pattern 30 in the display transferring structure 200 may correspond to each of the plurality of grooves 10 in the transferring structure 1 of FIGS. 8 to 11.

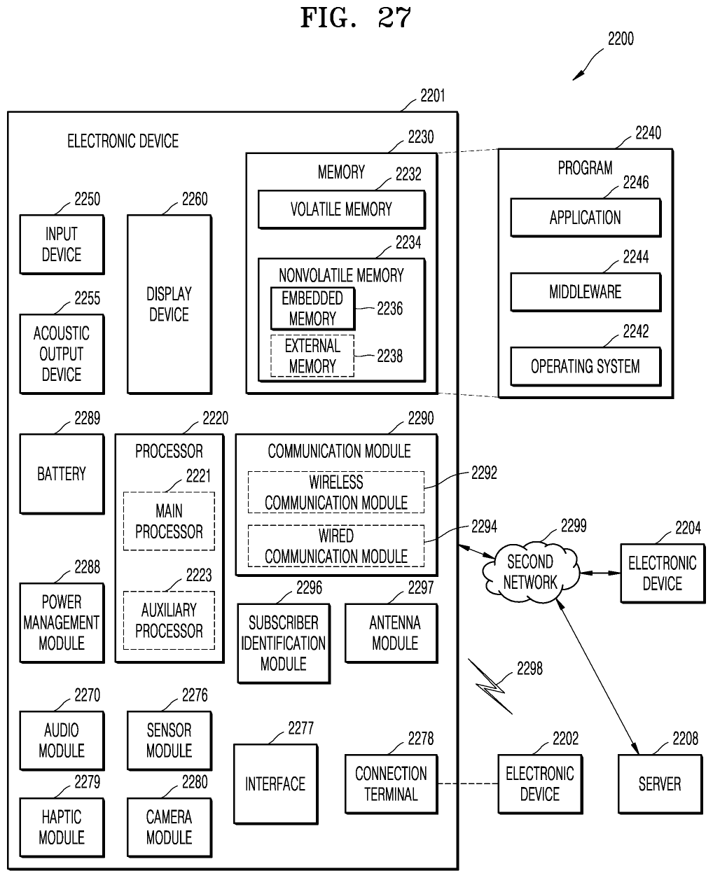

FIG. 27 is a block diagram of an electronic device 2201 including a display device 2260, according to an embodiment.

Referring to FIG. 27, the electronic device 2201 may be provided in a network environment 2200. In the network environment 2200, the electronic device 2201 may communicate with another electronic device 2202 through a first network 2298 (a short-range wireless communication network or the like) or communicate with another electronic device 2204 and/or a server 2208 through a second network 2299 (a long-range wireless communication network or the like). The electronic device 2201 may communicate with the electronic device 2204 via the server 2208. The electronic device 2201 may include a processor 2220, a memory 2230, an input device 2250, an acoustic output device 2255, the display device 2260, an audio module 2270, a sensor module 2276, an interface 2277, a haptic module 2279, a camera module 2280, a power management module 2288, a battery 2289, a communication module 2290, a subscriber identification module 2296, and/or an antenna module 2297. Some of these components may be omitted in the electronic device 2201, or other components may be added to the electronic device 2201. Some of these components may be implemented as one integrated circuit. For example, the sensor module 2276 (a fingerprint sensor, an iris sensor, an illuminance sensor, and the like) may be implemented by being embedded in the display device 2260 (a display or the like).

The processor 2220 may execute software (a program 2240 or the like) to control one or more other components (hardware and software components and the like) in the electronic device 2201, which are connected to the processor 2220, and perform various kinds of data processing or calculation. As a portion of the data processing or calculation, the processor 2220 may load, on a volatile memory 2232, a command and/or data received from another component (the sensor module 2276, the communication module 2290, or the like), process the command and/or the data stored in the volatile memory 2232, and store result data in a nonvolatile memory 2234. The processor 2220 may include a main processor 2221 (a central processing unit, an application processor, or the like) and an auxiliary process 2223 (a graphics processing unit, an image signal processor, a sensor hub processor, a communication processor, or the like) operable independently to or together with the main processor 2221. The auxiliary process 2223 may use less power than the main processor 2221 and perform a specialized function.

The auxiliary process 2223 may control functions and/or states related to some components (the display device 2260, the sensor module 2276, the communication module 2290, and the like) among the components of the electronic device 2201 instead of the main processor 2221 while the main processor 2221 is in an inactive state (a sleep state) or together with the main processor 2221 while the main processor 2221 is in an active state (an application execution state). The auxiliary process 2223 (the image signal processor, the communication processor, or the like) may be implemented as a portion of another component (the camera module 2280, the communication module 2290, or the like) functionally related thereto.

The memory 2230 may store various kinds of data required by a component (the processor 2220, the sensor module 2276, or the like) in the electronic device 2201. The data may include, for example, input data and/or output data with respect to software (the program 2240 or the like) and a command related to the software. The memory 2230 may include the volatile memory 2232 and/or the nonvolatile memory 2234.

The program 2240 may be stored as software in the memory 2230 and include an operating system 2242, middleware 2244, and/or an application 2246.

The input device 2250 may receive, from the outside (a user or the like) of the electronic device 2201, a command and/or data to be used for a component (the processor 2220 or the like) in the electronic device 2201. The input device 2250 may include a remote control, a microphone, a mouse, a keyboard, and/or a digital pen (a stylus pen or the like).

The acoustic output device 2255 may output an acoustic signal to the outside of the electronic device 2201. The acoustic output device 2255 may include a speaker and/or a receiver. The speaker may be used for a general purpose, such as multimedia playback or recording playback, and the receiver may be used to receive an incoming call. The receiver may be coupled as a portion of the speaker or implemented as an independent separate device.

The display device 2260 may visually provide information to the outside of the electronic device 2201. The display device 2260 may include a display, a hologram device, or a projector and control circuitry configured to control a corresponding device. The display device 2260 may be manufactured by the manufacturing method described with reference to FIGS. 1 to 26. The display device 2260 may include the display transferring structure 200 described with reference to FIGS. 24 to 26. The display device 2260 may include touch circuitry configured to sense a touch and/or sensor circuitry (a pressure sensor or the like) configured to measure a strength of a force generated by the touch.

The audio module 2270 may convert a sound into an electrical signal or reversely convert an electrical signal into a sound. The audio module 2270 may obtain a sound through the input device 2250 or output a sound through the acoustic output device 2255 and/or a speaker and/or headphones in another electronic device (the electronic device 2202 or the like) connected directly or wirelessly to the electronic device 2201.

The sensor module 2276 may sense an operating state (power, a temperature, and the like) of the electronic device 2201 or an external environmental state (a user state and the like) and generate an electrical signal and/or a data value corresponding to the sensed state. The sensor module 2276 may include a gesture sensor, a gyro sensor, an atmospheric sensor, a magnetic sensor, an acceleration sensor, a grip sensor, a proximity sensor, a color sensor, an infrared (IR) sensor, a biometric sensor, a temperature sensor, a humidity sensor, and/or an illuminance sensor.

The interface 2277 may support one or more designated protocols usable for the electronic device 2201 to be connected directly or wirelessly to another electronic device (the electronic device 2202 or the like). The interface 2277 may include a high definition multimedia interface (HDMI), a universal serial bus (USB) interface, a secure digital (SD) card interface, and/or an audio interface.

A connection terminal 2278 may include a connector through which the electronic device 2201 is physically connectable to another electronic device (the electronic device 2202 or the like). The connection terminal 2278 may include an HDMI connector, a USB connector, an SD card connector, and/or an audio connector (a headphones connector or the like).

The haptic module 2279 may convert an electrical signal into a mechanical stimulus (vibration, movement, or the like) or an electrical stimulus of which a user may be aware through tactile sensation or motor sensation. The haptic module 2279 may include a motor, a piezoelectric element, and/or an electrical stimulation device.

The camera module 2280 may capture a still image and a video. The camera module 2280 may include a lens assembly including one or more lenses, image sensors, image signal processors, and/or flashes. The lens assembly included in the camera module 2280 may collect light reflected from a subject that is a target of image capturing.

The power management module 2288 may manage power supplied to the electronic device 2201. The power management module 2288 may be implemented as a portion of a power management integrated circuit (PMIC).

The battery 2289 may supply power to the components in the electronic device 2201. The battery 2289 may include a non-rechargeable primary battery, a rechargeable secondary battery, and/or a fuel cell.

The communication module 2290 may establish a direct (wired) communication channel and/or a wireless communication channel between the electronic device 2201 and another electronic device (the electronic device 2202, the electronic device 2204, the server 2208, or the like) and support communication through the established communication channel. The communication module 2290 may operate independently to the processor 2220 (the application processor, or the like) and include one or more communication processors supporting direct communication and/or wireless communication. The communication module 2290 may include a wireless communication module 2292 (a cellular communication module, a short-range wireless communication module, a global navigation satellite system (GNSS) communication module, or the like) and/or a wired communication module 2294 (a local area network (LAN) communication module, a power line communication module, or the like). A corresponding communication module among these communication modules may communicate with another electronic device through the first network 2298 (a short-range communication network, such as Bluetooth, WiFi Direct, or infrared data association (IrDA)) or the second network 2299 (a long-range communication network, such as a cellular network, the Internet, or a computer network (a LAN, a wide area network (WAN), or the like). These various types of communication modules may be integrated into one component (a single chip or the like) or implemented by a plurality of separate components (a plurality of chips). The wireless communication module 2292 may confirm or authenticate the electronic device 2201 in a communication network, such as the first network 2298 and/or the second network 2299, by using subscriber information (an international mobile subscriber identity (IMSI) or the like) stored in the subscriber identification module 2296.

The antenna module 2297 may transmit or receive a signal and/or power to or from the outside (another electronic device or the like). An antenna may include a radiator including a conductive pattern formed on a substrate (a printed circuit board (PCB) or the like). The antenna module 2297 may include one or more antennas. If the antenna module 2297 includes a plurality of antennas, an antenna suitable for a communication scheme used in a communication network, such as the first network 2298 and/or the second network 2299, may be selected from among the plurality of antennas by the communication module 2290. Through the selected antenna, a signal and/or power may be exchanged between the communication module 2290 and another electronic device. Besides the antenna, other parts (a radio frequency integrated circuit (RFIC) and the like) may be included as a portion of the antenna module 2297.

Some of the components may be connected to each other through a communication scheme (a bus, a general purpose input and output (GPIO), a serial peripheral interface (SPI), a mobile industry processor interface (MIPI), or the like) between peripherals and exchange a signal with each other.

A command or data may be exchanged between the electronic device 2201 and the external electronic device 2204 via the server 2208 connected to the second network 2299. The other electronic devices 2202 and 2204 may be the same type as or different types from that of the electronic device 2201. All or some of operations executed by the electronic device 2201 may be executed by one or more of the other electronic devices 2202 and 2204 and the server 2208. For example, when the electronic device 2201 is supposed to perform a certain function or service, the electronic device 2201 may request one or more other electronic devices to perform a portion or the whole of the function or service, instead of executing the function or service therein. The one or more other electronic devices having received the request may execute an additional function or service related to the request and transmit a result of the execution to the electronic device 2201. To this end, cloud computing, distributed computing, and/or client-server computing may be employed.

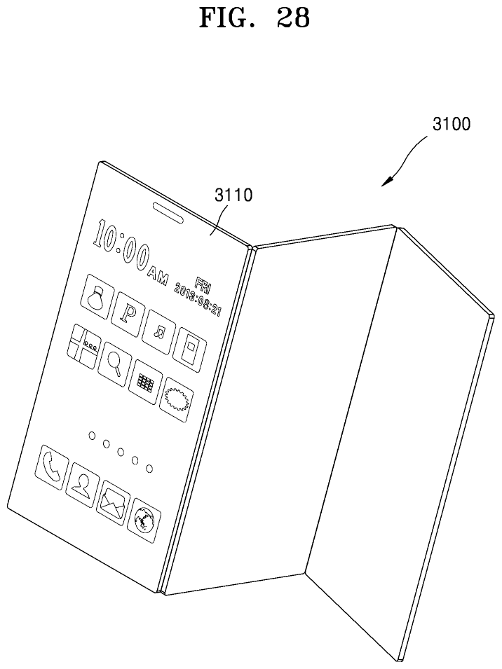

FIG. 28 illustrates an example in which an electronic device is applied to a mobile device 3100, according to an embodiment. The mobile device 3100 may include a display device 3110 according to an embodiment. The display device 3110 may include the display transferring structure 200 (see FIGS. 24 to 26). The display device 3110 may have a foldable structure and be applied to, for example, a multi-folder display. Although FIG. 28 shows that the mobile device 3100 is a folder-type display, the mobile device 3100 may also be applied to a general flat display.

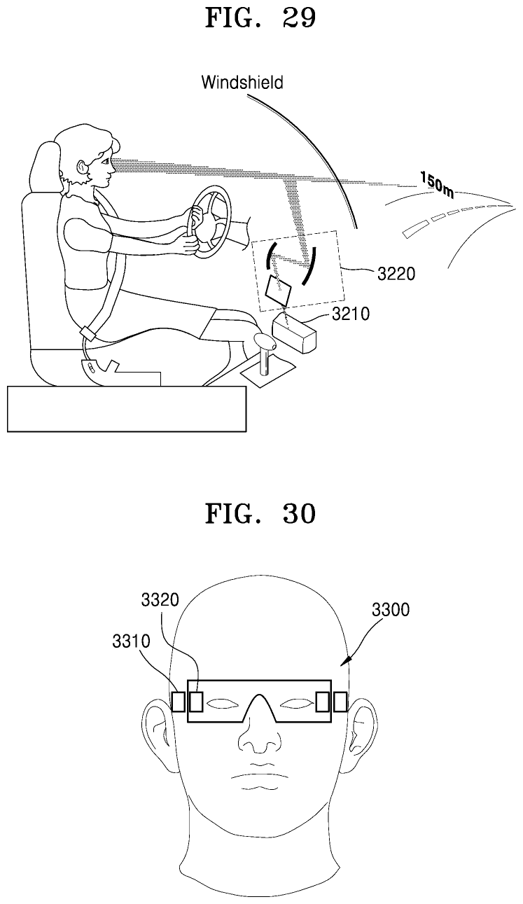

FIG. 29 illustrates an example in which a display device is applied to a vehicle, according to an embodiment. The display device may be applied to a head-up display device for a vehicle. The head-up display device may include a display device 3210 provided to one region of the vehicle and at least one optical path change member 3220 configured to change an optical path so that a driver may view an image generated by the display device 3210.

FIG. 30 illustrates an example in which a display device is applied to augmented reality glasses 3300 or virtual reality glasses, according to an embodiment. The augmented reality glasses 3300 may include a projection system 3310 configured to form an image and at least one element 3320 guiding the image from the projection system 3310 toward the eyes of a user. The projection system 3310 may include the display transferring structure 200 (see FIGS. 24 and 25).

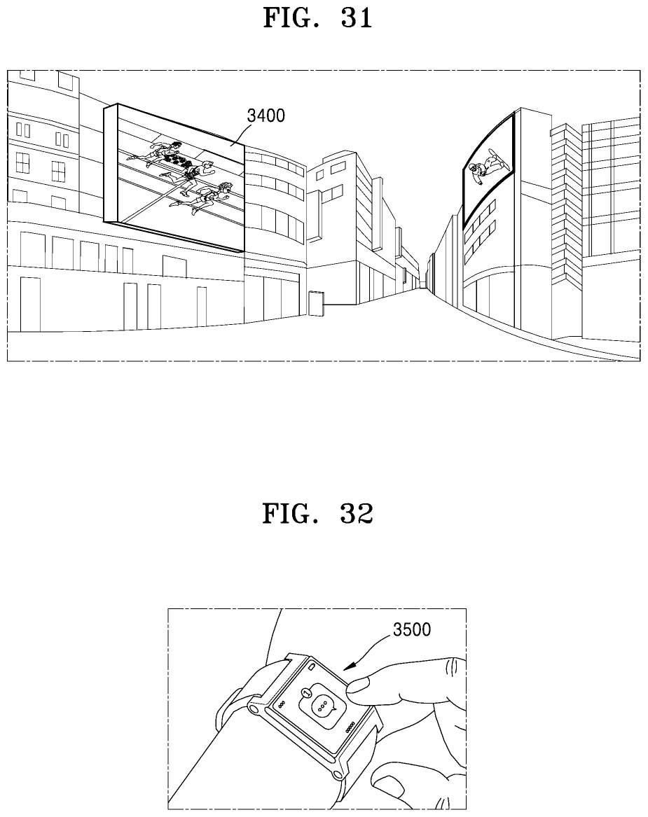

FIG. 31 illustrates an example in which a display device is applied to a large-scale signage 3400, according to an embodiment. The signage 3400 may be used for an outdoor advertisement using a digital information display and control advertising content and the like through a communication network. The signage 3400 may be implemented by, for example, the electronic device 2201 described with reference to FIG. 27.

FIG. 32 illustrates an example in which a display device is applied to a wearable display 3500, according to an embodiment. The wearable display 3500 may include the display transferring structure 200 (see FIGS. 24 to 26) and be implemented by electronic device 2201 described with reference to FIG. 27.

A display device according to an embodiment may also be applied to various products, such as a rollable TV and a stretchable display.

A transferring structure according to an embodiment may be used to efficiently insert a plurality of micro semiconductor chips into a plurality of grooves, respectively, when micro semiconductor chips are transferred in a wet manner.

A method of transferring micro semiconductor chips, according to an embodiment, may efficiently transfer the micro semiconductor chips to a substrate.

A display device according to an embodiment may be applied to products employing a display transferring structure to which micro semiconductor chips are transferred.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A transferring structure comprising:
a transfer substrate having a plurality of grooves; and
a plurality of micro semiconductor chips transferred to the plurality of grooves, respectively, each of the plurality of micro semiconductor chips having a width w2,
wherein a minimum space between adjacent two of the plurality of micro semiconductor chips transferred to the plurality of grooves is 100% to 200% of width w2.

2. The transferring structure of claim 1, wherein a width of each of the plurality of grooves is greater than 100% and less than 150% of the width of each of the plurality of micro semiconductor chips.

3. The transferring structure of claim 1, wherein the micro semiconductor chip has a plurality of electrodes, and positions of the plurality of electrodes form point symmetry with reference to a central part of the micro semiconductor chip.

4. The transferring structure of claim 1, wherein each of the plurality of grooves has a size such that each of the plurality of micro semiconductor chips is movable therein, and each of the plurality of micro semiconductor chips is located at a same position inside a respective one of the plurality of grooves.

5. The transferring structure of claim 1, wherein a depth of each of the plurality of grooves is less than a thickness of the micro semiconductor chip.

6. The transferring structure of claim 1, wherein each of the plurality of grooves has a size such that each of the plurality of micro semiconductor chips is accommodated therein.

7. The transferring structure of claim 6, wherein a bottom surface of each of the plurality of grooves has a planar shape with a short side and a long side that is perpendicular to the short side, the short side is greater than the width of the micro semiconductor chip and less than or equal to two times the width of the micro semiconductor chip, and the long side is greater than two times the width of the micro semiconductor chip.

8. The transferring structure of claim 7, wherein the long side is greater than or equal to three times the width of the micro semiconductor chip and less than four times the width of the micro semiconductor chip.

9. The transferring structure of claim 6, wherein a bottom surface of each of the plurality of grooves has an L shape.

10. A transfer substrate having a plurality of grooves into which at least one micro semiconductor chip is inserted,
wherein a distance between adjacent two of the plurality of grooves is 80% to 170% inclusive of a width of a bottom surface of the groove.

11. The transfer substrate of claim 10, wherein the distance between adjacent two of the plurality of grooves is 100% to 130% inclusive of the width of the bottom surface of the groove.

12. A display device comprising a display transferring structure to which a plurality of micro semiconductor chips are transferred,
wherein a spacing of the plurality of micro semiconductor chips satisfy Equation 1 below:
$$100 ( \% ) \leq \frac{a}{b} \times 100 ( \% ) \leq 200 ( \% ) \qquad Equation 1$$
where a denotes a minimum space between adjacent two of the plurality of micro semiconductor chips, and b denotes a size of the micro semiconductor chip.

13. The display device of claim 12, wherein the spacing of the plurality of micro semiconductor chips satisfy the requirement of Equation 2 below:
$$120 ( \% ) \leq \frac{a}{b} \times 100 ( \% ) \leq 160 ( \% ) \qquad Equation 2$$

14. The display device of claim 12, wherein the plurality of micro semiconductor chips have a diamond pentile pixel arrangement.
